(19) United States
(12) Patent Application Publication
(10) Pub. No.: US 2024/0144002 A1
(43) Pub. Date: May 2, 2024

(54) WAFER HOTSPOT-FIXING LAYOUT HINTS BY MACHINE LEARNING

(71) Applicant: SanDisk Technologies LLC, Addison, TX (US)

(72) Inventors: Chen-Che Huang, San Jose, CA (US); Lauren Matsumoto, Sunnyvale, CA (US); Chunming Wang, Fremont, CA (US)

(73) Assignee: SanDisk Technologies LLC, Addison, TX (US)

(21) Appl. No.: 18/355,331

(22) Filed: Jul. 19, 2023

Related U.S. Application Data
(60) Provisional application No. 63/419,872, filed on Oct. 27, 2022.

(51) Int. Cl. G06N 3/08

(52) U.S. Cl. CPC G06N 3/08

(57) ABSTRACT

A system that includes a machine learning model that is configured to receive an input layout file that includes a portion of an integrated circuit layout that has a previously identified wafer hotspot, match the previously identified wafer hotspot to one of a plurality of categories of wafer hotspot types, and output a proposed layout modification associated with the matching category of wafer hotspot types.

### CLAIM OF PRIORITY

The present application claims priority from U.S. Provisional Patent Application No. 63/419,872, entitled “WAFER HOTSPOT-FIXING LAYOUT HINTS BY MACHINE LEARNING,” filed Oct. 27, 2022, which is incorporated by reference herein in its entirety.

### BACKGROUND

Integrated circuit fabrication involves various detailed processes, including lithography and etching. As integrated circuit feature sizes decrease, integrated circuit layouts likewise shrink. As a result of limitations in lithography and etching, defects may occur during manufacturing of integrated circuit die on semiconductor wafers. For example, such fabrication defects may include broken lines, shorts between adjacent lines, holes not completely opening, and other similar defects. Such defects, which are not a result of random processing variations from die-to-die, are referred to herein as “wafer hotspots.”

Wafer hotspots may cause an integrated circuit die to fail operation, and thus must be corrected. Once a wafer hotspot has been identified, a traditional solution has been for an experienced layout engineer to determine a proposed layout modification to eliminate the wafer hotspot, and then run simulations to verify that the proposed layout modification is satisfactory. This process typically is repeated through several time-consuming trial-and-error iterations, after which a revised layout is achieved that is free of wafer hotspots.

In addition to being very time-consuming, such a traditional technique requires that the layout engineer have substantial experience to successfully resolve wafer hotspot issues. As a result, less experienced layout engineers often are incapable of correcting wafer hotspots. Thus, fixing wafer hotspots presents numerous challenges.

### BRIEF DESCRIPTION OF THE DRAWINGS

Like-numbered elements refer to common components in the different figures.

FIG. 1 is a simplified diagram of an embodiment of system for providing proposed layout modifications to eliminate previously identified wafer hotspots.

FIG. 2A1-2E1 depict example input layout files that depict portions of an integrated circuit layout that include a previously identified wafer hotspot.

FIG. 2A2-2E2 depict modified layouts corresponding to the input layout files of FIGS. 2A1-2E1, respectively.

FIG. 3A depicts a simplified block diagram of a training system for generating a trained machine learning model.

FIG. 3B depicts a simplified block diagram of a matching system for using the trained machine learning model of FIG. 3A.

FIG. 4 is a simplified diagram of another embodiment of system for providing proposed layout modifications to eliminate previously identified wafer hotspots.

FIG. 5A1-5C1 depict example input layout files that depict portions of an integrated circuit layout that include a previously identified wafer hotspot.

FIG. 5A2-5C2 depict modified layouts corresponding to the input layout files of FIGS. 5A1-5C1, respectively.

FIG. 6A depicts a simplified block diagram of a training system for generating a trained machine learning model.

FIG. 6B depicts a simplified block diagram of a matching system for using the trained machine learning model of FIG. 6A.

FIG. 7 depicts an example graphical user interface to facilitate training and implementation of machine learning models for providing proposed layout modifications to eliminate previously identified wafer hotspots in integrated circuit layouts.

### DETAILED DESCRIPTION

Technology is described for a machine learning system that is configured to receive an input layout file that includes a portion of an integrated circuit layout that has a previously identified wafer hotspot, match the previously identified wafer hotspot to one of a plurality of categories of wafer hotspot types, and output a proposed layout modification associated with the matching category of wafer hotspot types.

Without wanting to be bound by any particular theory, it is believed that such machine learning systems may facilitate correction of wafer hotspots. Without wanting to be bound by any particular theory, it is believed that such machine learning systems may enable less experienced layout engineers to more easily and quickly correct wafer hotspots.

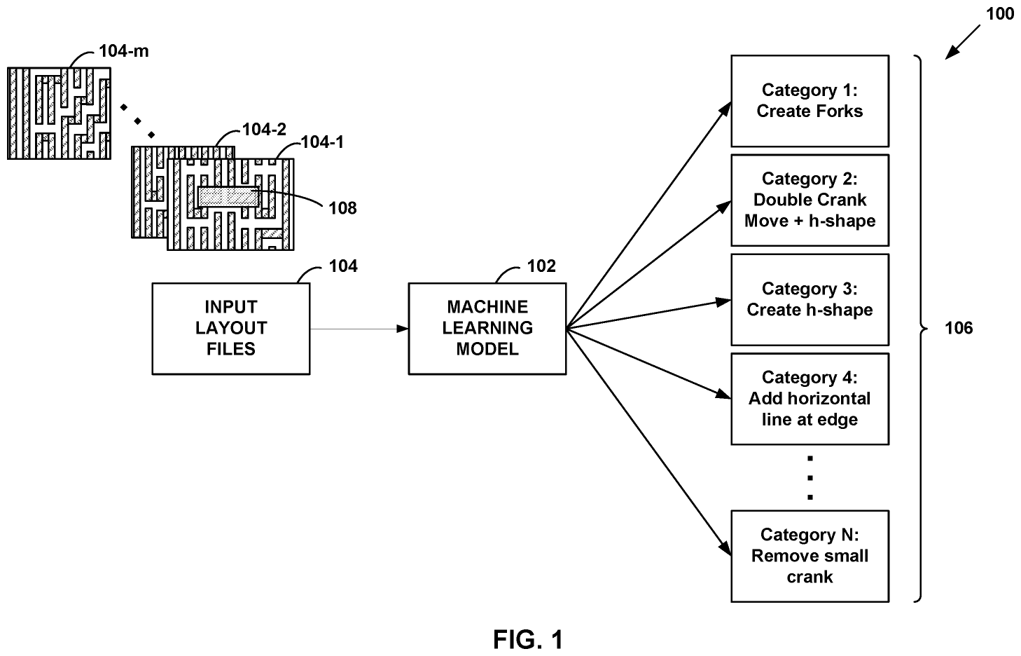

FIG. 1 is a simplified diagram of an embodiment of a system 100 for providing proposed layout modifications to eliminate previously identified wafer hotspots. In an embodiment, system 100 includes a machine learning model 102 configured to receive one or more input layout files 104 (e.g., input layout files 104-1, 104-2, . . . , 104-m), and output a corresponding category indicator 106 for each input layout file 104. In an embodiment, machine learning model 102 may be implemented on a computing device, such as a computer, workstation, tablet, smartphone or other similar computing device.

In an embodiment, each input layout file 104 depicts a portion of an integrated circuit layout that includes a previously identified wafer hotspot. For example, a simulation tool or other technique may be used to identify wafer hotspots in a layout.

In an embodiment, input layout files 104 include Graphic Design System (GDS) data files. GDS is a binary file format that represents layout data in a hierarchical format. GDS files contain pattern layout designs. Persons of ordinary skill in the art will understand that input layout files 104 may include data in other file formats.

In an embodiment, machine learning model 102 is an artificial neural network configured to analyze visual imagery. In an embodiment, machine learning model 102 is a convolutional neural network.

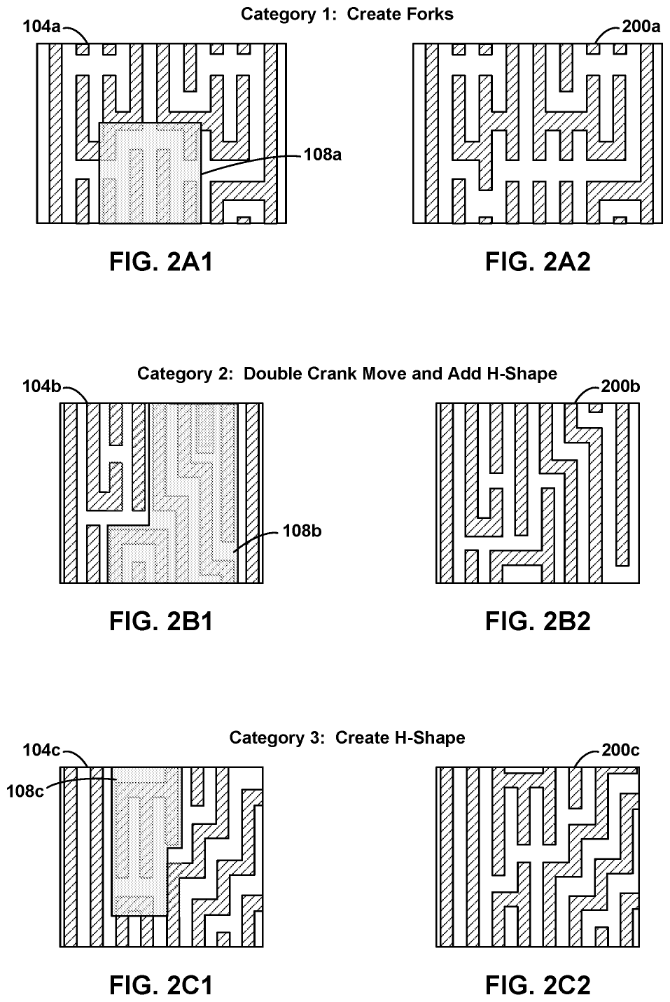

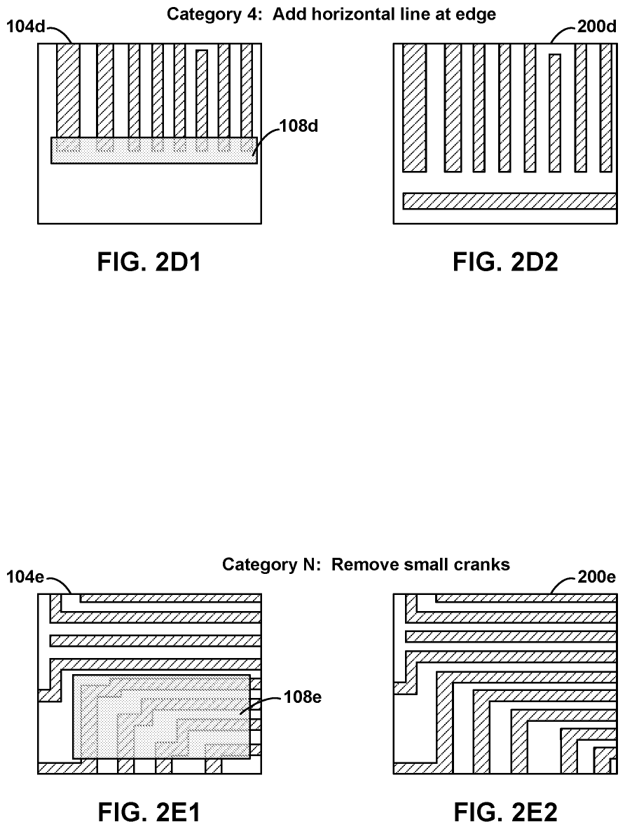

In an embodiment, each input layout file 104 includes a hotspot label 108 that designates the previously identified wafer hotspot in input layout file 104. For example, FIG. 2A1 depicts an example input layout file 104a that depicts a portion of an integrated circuit layout that includes a previously identified wafer hotspot. Example input layout file 104a includes hotspot label 108a that designates the previously identified wafer hotspot in input layout file 104a. In the example depicted in FIG. 2A1, hotspot label 108a is a shaded object, although other types of labels may be used.

Similarly, FIG. 2B1 depicts an example input layout file 104b that depicts a portion of an integrated circuit layout that includes a previously identified wafer hotspot. Example input layout file 104b includes hotspot label 108b that designates the previously identified wafer hotspot in input layout file 104b.

Likewise, FIGS. 2C1-2E1 depict example input layout files 104c-104e, respectively, each of which depicts a portion of an integrated circuit layout that includes a previously identified wafer hotspot. Example input layout files 104c-104e include hotspot labels 108c-108e, respectively, that designate the previously identified wafer hotspots in the input layout files 104c-104e, respectively.

Referring again to FIG. 1, in an embodiment, machine learning model 102 is an artificial neural network trained to receive an input layout file 104, and match the previously identified wafer hotspot in input layout file 104 to one of N categories of wafer hotspot types. In an embodiment, each category has a corresponding category indicator 106 (e.g., one or more numbers, letters, symbols, or other similar indicia). For simplicity, the remaining description will use the phrase “matching category indicator 106” to refer to the category that matches the previously identified wafer hotspot.

In an embodiment, each category indicator 106 has an associated text description of proposed layout modifications to eliminate the matching previously identified wafer hotspot from the layout. In an embodiment, machine learning model 102 outputs the matching category indicator 106. In an embodiment, machine learning model 102 additionally or alternatively outputs the text description associated with the matching category indicator 106.

For example, a first category (Category 1) may be associated with a proposed layout modification “Create Forks,” a second category (Category 2) may be associated with a proposed layout modification “Double Crank Move and Add H-Shape,” a third category (Category 3) may be associated with a proposed layout modification “Create H-shape,” a fourth category (Category 4) may be associated with a proposed layout modification “Add horizontal line at edge,” and so on through an N-th category (Category N) that may be associated with a proposed layout modification “Remove small crank.” In embodiments, N may be 16 or some other number categories of wafer hotspots.

In embodiments, each associated text description of proposed layout modifications is intended to facilitate the elimination of the matching previously identified wafer hotspot. For example, a layout engineer may use the described proposed layout modification as a guide for modifying the layout to eliminate the previously identified wafer hotspot.

For example, input layout file 104a of FIG. 2A1 includes a previously identified wafer hotspot designated by hotspot label 108a. The previously identified wafer hotspot matches Category 1, which has an associated text description of proposed layout modifications “Create Forks.” FIG. 2A2 depicts a modified layout 200a which is an example of a result of applying the proposed layout modification “Create Forks” to input layout file 104a.

Input layout file 104b of FIG. 2B1 includes a previously identified wafer hotspot designated by hotspot label 108b. The previously identified wafer hotspot matches Category 2, which has an associated text description of proposed layout modifications “Double Crank Move and Add H-Shape.” FIG. 2B2 depicts a modified layout 200b which is an example of a result of applying the proposed layout modification “Double Crank Move and Add H-Shape” to input layout file 104b.

Input layout file 104c of FIG. 2C1 includes a previously identified wafer hotspot designated by hotspot label 108c. The previously identified wafer hotspot matches Category 3, which has an associated text description of proposed layout modifications “Create H-Shape.” FIG. 2C2 depicts a modified layout 200c which is an example of a result of applying the proposed layout modification “Create H-Shape” to input layout file 104c.

Input layout file 104d of FIG. 2D1 includes a previously identified wafer hotspot designated by hotspot label 108d. The previously identified wafer hotspot matches Category 4, which has an associated text description of proposed layout modifications “Add horizontal line at edge.” FIG. 2D2 depicts a modified layout 200d which is an example of a result of applying the proposed layout modification “Add horizontal line at edge” to input layout file 104d.

Input layout file 104e of FIG. 2E1 includes a previously identified wafer hotspot designated by hotspot label 108e. The previously identified wafer hotspot matches Category N, which has an associated text description of proposed layout modifications “Remove small cranks.” FIG. 2E2 depicts a modified layout 200e which is an example of a result of applying the proposed layout modification “Remove small cranks” to input layout file 104e.

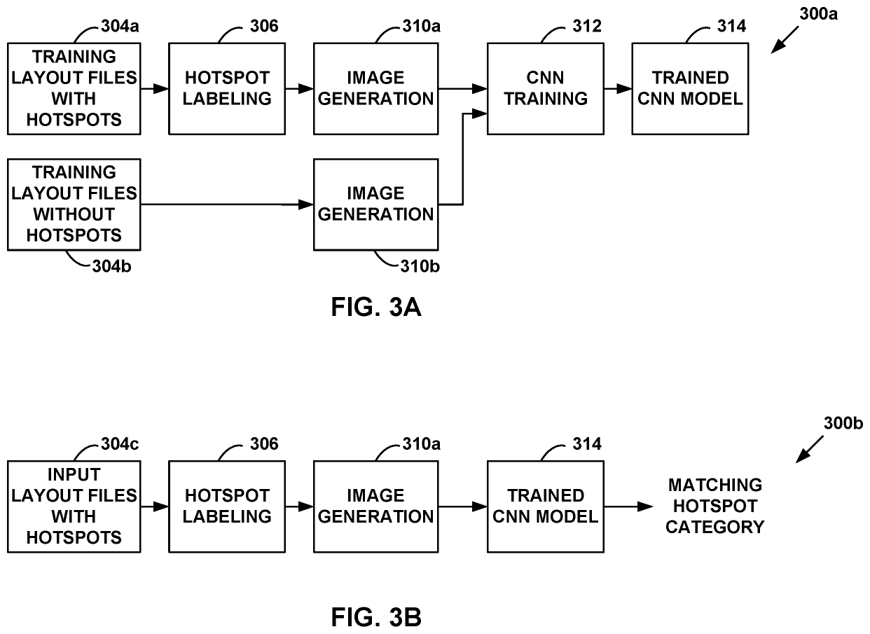

Referring again to FIG. 1, in an embodiment machine learning model 102 is trained to match previously identified wafer hotspots in one or more training input images to one of N categories of wafer hotspots. FIG. 3A depicts a simplified block diagram of a training system 300a for training machine learning model 102 to perform such matching. Persons of ordinary skill in the art will understand that some or all of the elements of training system 300a may be implemented on a computing device, such as a computer, workstation, tablet, smartphone or other similar computing device.

In the illustrated embodiment, training system 300a includes a first set of training layout files 304a and a second set of training layout files 304b. In an embodiment, first set of training layout files 304a and second set of training layout files 304b each include one or more input files that may include GDS data.

In an embodiment, each input file in first set of training layout files 304a has a corresponding input file in second set of training layout files 304b. In an embodiment, the corresponding input files pertain to a same portion of an integrated circuit layout, but the input file in first set of training layout files 304a includes a wafer hotspot, whereas the corresponding input file in second set of training layout files 304b does not include a wafer hot spot. In other words, an input file in second set of training layout files 304b includes data pertaining to a “corrected” version of the corresponding input file in first set of training layout files 304a.

In an embodiment, input files from first set of training layout files 304a are processed by a hotspot labeling block 306, which is configured to designate the wafer hotspot in each input layout file of first set of training layout files 304a. In an embodiment, the data output from hotspot labeling block 306 are input to an image generation block 310a, and the data output from second set of training layout files 304b are input to an image generation block 310b. In an embodiment, image generation block 310a and image generation block 310b are each configured to generate images in either TIFF, BMP, JPG, JPEG or PNG format, although other formats may be used.

In an embodiment, the outputs of image generation block 310a and image generation block 310b are corresponding images that depict a same portion of an integrated circuit layout, but the images output from image generation block 310a each include a wafer hotspot, whereas the corresponding images output from image generation block 310b do not include a wafer hot spot.

In an embodiment, images from image generation block 310a and image generation block 310b are input to a convolutional neural network (CNN) training block 312, which is configured to generate a trained CNN model 314 from the received input image data. As known in the art, a convolutional neural network is a class of artificial neural network most commonly applied to analyze visual imagery. In an embodiment, CNN training block 312 is configured to generate a trained CNN model 314 that may be used to match previously identified wafer hotspots to one of N categories of wafer hotspots.

In an embodiment, trained CNN model 314 may then be deployed to match previously identified wafer hotspots on input layout files (e.g., input layout files 104 of FIG. 1) to one of N categories of wafer hotspots. FIG. 3B depicts a simplified block diagram of a matching system 300b for using trained CNN model 314 to perform such matching. Persons of ordinary skill in the art will understand that some or all of the elements of matching system 300b may be implemented on a computing device, such as a computer, workstation, tablet, smartphone or other similar computing device.

In particular, matching system 300b includes hotspot labeling block 306, image generation block 310a and trained CNN model 314 from FIG. 3A. In an embodiment, input layout files 304c include previously identified wafer hotspots, and are input to matching system 300b, which matches the previously identified wafer hotspots to one of N categories of wafer hotspots, such as described above.

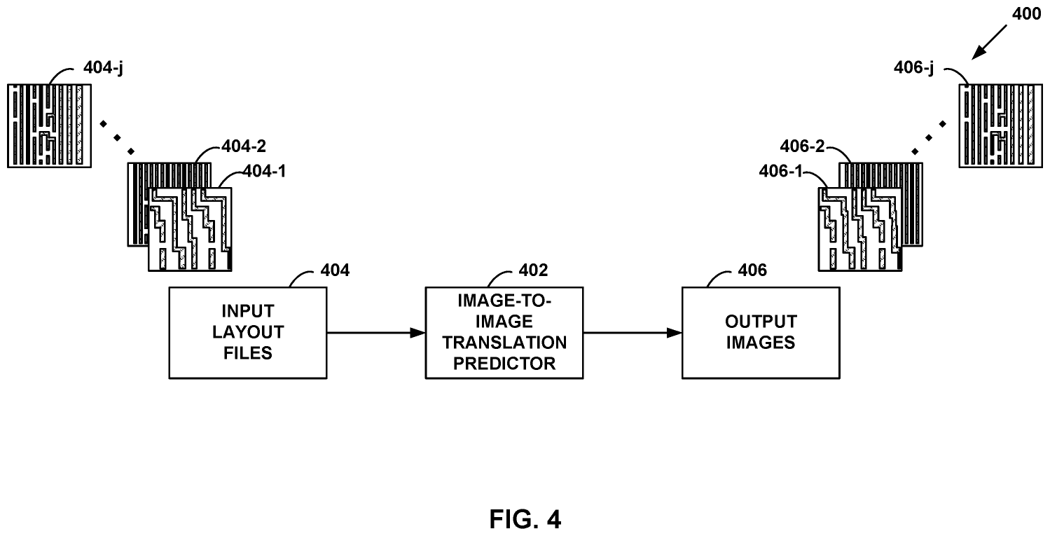

FIG. 4 is a simplified diagram of an embodiment of system 400 for providing proposed layout modifications to eliminate previously identified wafer hotspots. In an embodiment, system 400 includes machine learning model 402 configured to receive one or more input layout files 404 (e.g., input layout files 404-1, 404-2, . . . , 404-j), and output a corresponding output image file 406 (e.g., output image files 406-1, 406-2, . . . , 406-j) for each input image 404. In an embodiment, machine learning model 402 may be implemented on a computing device, such as a computer, workstation, tablet, smartphone or other similar computing device.

In an embodiment, each input layout file 404 depicts a portion of an integrated circuit layout that includes a previously identified wafer hotspot. For example, a simulation tool or other technique may be used to identify wafer hotspots in a layout. In an embodiment, each output image file 406 depicts a same portion of an integrated circuit layout as the portion depicted in the corresponding input layout file 404, but including proposed changes to the integrated circuit layout to eliminate the previously identified wafer hotspot.

In an embodiment, input layout files 404 include GDS data files. Persons of ordinary skill in the art will understand that input layout files 404 may include data in other file formats.

In an embodiment, machine learning model 402 is an image-to-image translation predictor, which is a type of artificial neural network configured to analyze visual imagery to perform pixel-wise prediction. In the remaining description, machine learning model 402 also will be referred to as image-to-image translation predictor 402.

In an embodiment, image-to-image translation is a process of transforming an image from one domain to another, where the goal is to learn the mapping between an input image and an output image. This task has been generally performed by using a training set of aligned image pairs.

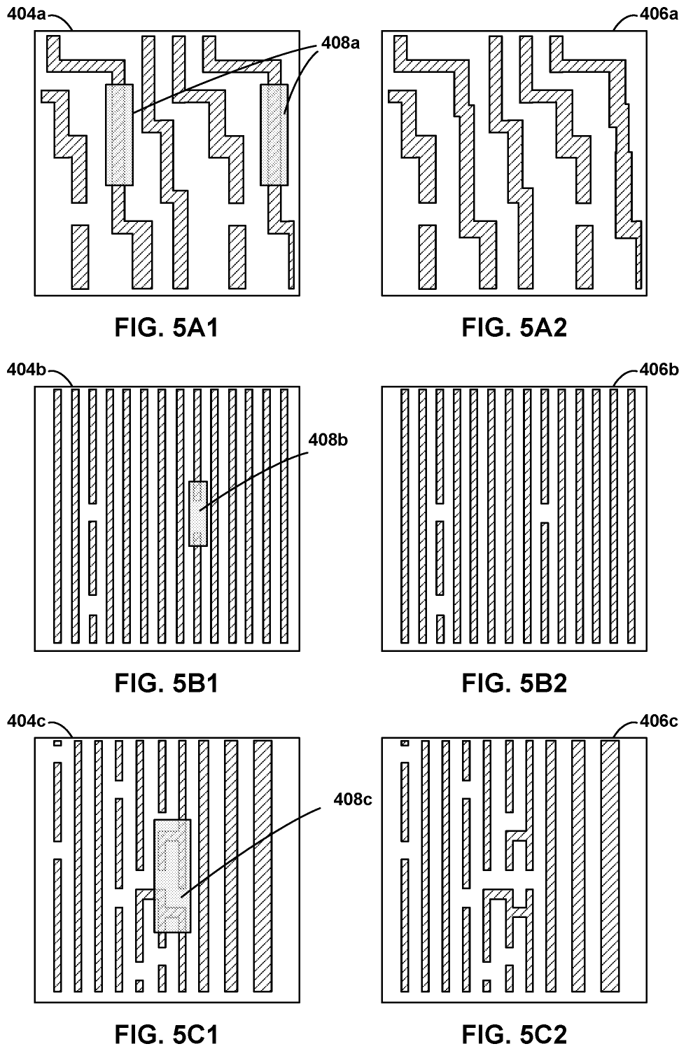

In an embodiment, each input layout file 404 includes a hotspot label 408 that designates the previously identified wafer hotspot in input layout file 404. For example, FIG. 5A1 depicts an example input layout file 404a that depicts a portion of an integrated circuit layout that includes a previously identified wafer hotspot. Example input layout file 404a includes hotspot label 408a that designates the previously identified wafer hotspot in input layout file 404a. In the example depicted in FIG. 5A1, hotspot label 408a is a shaded object, although other types of labels may be used.

Similarly, FIG. 5B1 depicts an example input layout file 404b that depicts a portion of an integrated circuit layout that includes a previously identified wafer hotspot. Example input layout file 404b includes hotspot label 408b that designates the previously identified wafer hotspot in input layout file 404b.

Likewise, FIG. 5C1 depicts an example input layout file 404c that depicts a portion of an integrated circuit layout that includes a previously identified wafer hotspot. Example input layout file 404c includes hotspot label 408c that designates the previously identified wafer hotspots in the input layout file 404c.

Referring again to FIG. 4, in an embodiment image-to-image translation predictor 402 is an artificial neural network trained to receive an input layout file 404, and match the previously identified wafer hotspot 408 in input layout file 404 to a corrected layout portion, and generate a corresponding output image file 406 that depicts a same portion of an integrated circuit layout as the portion depicted in the corresponding input layout file 404, but with proposed changes to the integrated circuit layout to eliminate the previously identified wafer hotspot. For example, a layout engineer may use the corresponding output image 406 as a guide for modifying the layout to eliminate the previously identified wafer hotspot.

For example, input layout file 404a of FIG. 5A1 includes a previously identified wafer hotspot designated by hotspot label 408a. In an embodiment, image-to-image translation predictor 402 receives input layout file 404a, matches previously identified wafer hotspot 408a to a corrected layout portion, and generates a corresponding output image file 406a (FIG. 5A2) that depicts a same portion of an integrated circuit layout as the portion depicted in the corresponding input layout file 404a, but with proposed changes to the integrated circuit layout to eliminate the previously identified wafer hotspot.

In another example, input layout file 404b of FIG. 5B1 includes a previously identified wafer hotspot designated by hotspot label 408b. In an embodiment, image-to-image translation predictor 402 receives input layout file 404b, matches previously identified wafer hotspot 408b to a corrected layout portion, and generates a corresponding output image file 406b (FIG. 5B2) that depicts a same portion of an integrated circuit layout as the portion depicted in the corresponding input layout file 404b, but with proposed changes to the integrated circuit layout to eliminate the previously identified wafer hotspot.

In yet another example, input layout file 404c of FIG. 5C1 includes a previously identified wafer hotspot designated by hotspot label 408c. In an embodiment, image-to-image translation predictor 402 receives input layout file 404c, matches previously identified wafer hotspot 408c to a corrected layout portion, and generates a corresponding output image file 406c (FIG. 5C2) that depicts a same portion of an integrated circuit layout as the portion depicted in the corresponding input layout file 404c, but with proposed changes to the integrated circuit layout to eliminate the previously identified wafer hotspot.

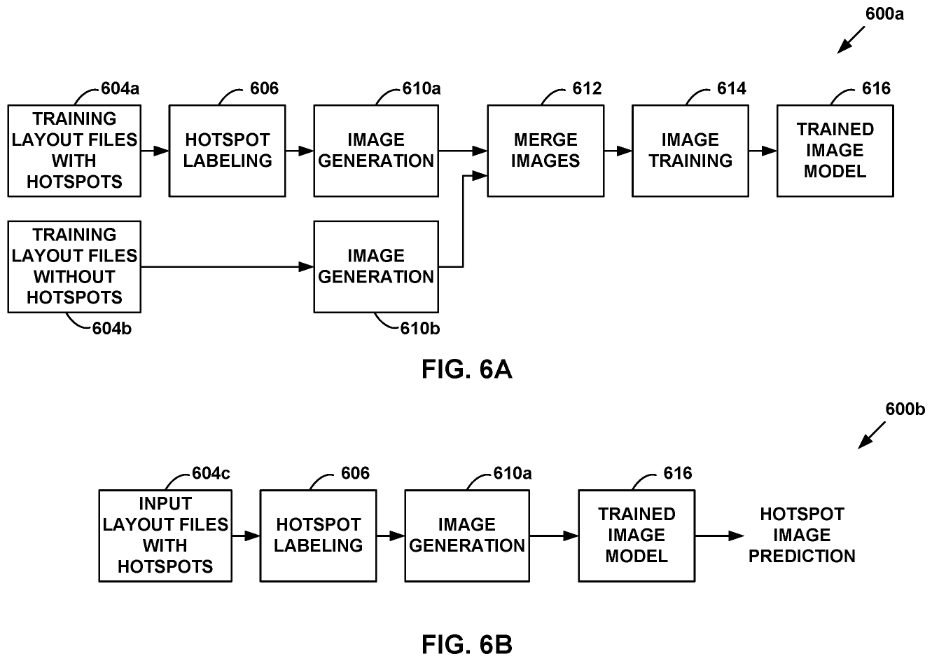

Referring again to FIG. 4, in an embodiment image-to-image translation predictor 402 is trained to learn a mapping between an input image and an output image for eliminating previously identified wafer hotspots. FIG. 6A depicts a simplified block diagram of a training system 600a for training image-to-image translation predictor 402 to perform such mapping. Persons of ordinary skill in the art will understand that some or all of the elements of training system 600a may be implemented on a computing device, such as a computer, workstation, tablet, smartphone or other similar computing device.

In the illustrated embodiment, training system 600a includes a first set of training layout files 604a and a second set of training layout files 604b. In an embodiment, first set of training layout files 604a and second set of training layout files 604b each include one or more input files that may include GDS data.

In an embodiment, each input file in first set of training layout files 604a has a corresponding input file in second set of training layout files 604b. In an embodiment, the corresponding input files pertain to a same portion of an integrated circuit layout, but the input file in first set of training layout files 604a includes a wafer hotspot, whereas the corresponding input file in second set of training layout files 604b does not include a wafer hot spot. In other words, an input file in second set of training layout files 604b includes data pertaining to a “corrected” version of the corresponding input file in first set of training layout files 604a.

In an embodiment, input files from first set of training layout files 604a are processed by a hotspot labeling block 606, which is configured to designate the wafer hotspot in each input file of first set of training layout files 604a. In an embodiment, the data output from hotspot labeling block 606 are input to an image generation block 610a, and the data output from second set of training layout files 604b are input to an image generation block 610b. In an embodiment, image generation block 610a and image generation block 610b are each configured to generate images in either TIFF, BMP, JPG, JPEG or PNG format, although other formats may be used.

In an embodiment, the outputs of image generation block 610a and image generation block 610b are corresponding images that depict a same portion of an integrated circuit layout, but the images output from image generation block 610a each include a wafer hotspot, whereas the corresponding images output from image generation block 610b do not include a wafer hot spot.

In an embodiment, images from image generation block 610a and image generation block 610b are input to an image merging block 612 which is configured to merge the input images together. The merged image file is input to an image training bock 614, which is configured to generate a trained image model 616 from the received merged input image data. In an embodiment, image training block 614 is configured to generate a trained image model 616 that may be used to match a previously identified wafer hotspot to a corrected layout portion, and generate a corresponding output image file with proposed changes to the integrated circuit layout to eliminate the previously identified wafer hotspot.

In an embodiment, trained image model 616 may then be deployed to match previously identified wafer hotspots on input layout files (e.g., input layout files 404 of FIG. 4) and generate a corresponding output image file with proposed changes to the integrated circuit layout to eliminate the previously identified wafer hotspot. FIG. 6B depicts a simplified block diagram of a matching system 600b for using trained image model 616 to perform such matching.

In particular, matching system 600b includes hotspot labeling block 606, image generation block 610a and trained image model 616 from FIG. 6A. In an embodiment, input layout files 604c include previously identified wafer hotspots, and are input to matching system 600b, which matches the previously identified wafer hotspots and generates a corresponding output image file with proposed changes to the integrated circuit layout to eliminate the previously identified wafer hotspot, such as described above. Persons of ordinary skill in the art will understand that some or all of the elements of matching system 600b may be implemented on a computing device, such as a computer, workstation, tablet, smartphone or other similar computing device.

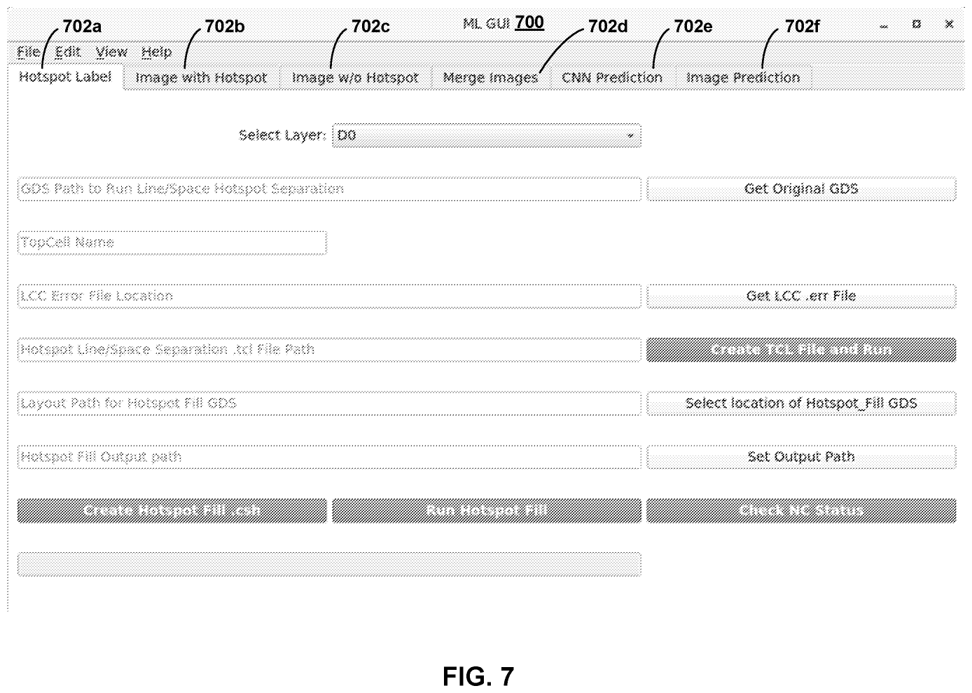

The example systems described above may be implemented and include a graphical user interface (GUI) to facilitate training and implementation of machine learning models for providing proposed layout modifications to eliminate previously identified wafer hotspots in integrated circuit layouts. FIG. 7 depicts an example of such a machine learning graphical user interface 700. In an embodiment, machine learning graphical user interface 700 includes multiple tabs 702 for implementing an example workflow used to train machine learning models such as described above and depicted in the example training systems depicted in FIGS. 3A and 6A, and for an example workflow for implementing the trained machine learning models such as described above and depicted in the example implementation systems depicted in FIGS. 3B and 6B.

For example, a first tab 702a (labeled “Hotspot Label”) includes various user settings pertaining to hotspot labeling block 306 in FIGS. 3A-3B and hotspot labeling block 606 in FIGS. 6A-6B, a second tab 702b (labeled “Image with Hotspot”) includes various user settings pertaining to image generation block 310a in FIGS. 3A-3B and image generation block 610a in FIGS. 6A-6B, a third tab 702c (labeled “Image w/o Hotspot”) includes various user settings pertaining to image generation block 310b in FIG. 3A and image generation block 610b in FIG. 6A, a fourth tab 702d (labeled “Merge Images”) includes various user settings pertaining to image merging block 612 in FIG. 6A, a fifth tab (labeled “CNN Prediction”) includes various user settings pertaining to CNN training block 312 in FIG. 3A and hotspot matching in FIG. 3B, and a sixth tab (labeled “Image Prediction”) includes various user settings pertaining to image training block 614 in FIG. 6A and hotspot image prediction in FIG. 6B.

Persons of ordinary skill in the art will understand that other user interfaces may be used, that graphical user interfaces with more or fewer than six tabs may be used, and that graphical user interfaces that include tabs other than those depicted in FIG. 7 may be used.

One embodiment includes system that includes a machine learning model that is configured to receive an input layout file that includes a portion of an integrated circuit layout that has a previously identified wafer hotspot, match the previously identified wafer hotspot to one of a plurality of categories of wafer hotspot types, and output a proposed layout modification associated with the matching category of wafer hotspot types.

One embodiment includes apparatus that includes a first block configured to designate a previously identified wafer hotspot in an input layout file that includes a portion of an integrated circuit layout, a second block configured to convert information from the input layout file to generate an image of the portion of the integrated circuit layout with the previously identified wafer hotspot, and a third block including a machine learning model configured to match the previously identified wafer hotspot to one of a plurality of categories of wafer hotspot types.

One embodiment includes an apparatus that includes a first block configured to designate a previously identified wafer hotspot in an input layout file that includes a portion of an integrated circuit layout, a second block configured to convert information from the input layout file to generate an image of the portion of the integrated circuit layout with the previously identified wafer hotspot, and a third block including an image-to-image translation predictor configured to match the previously identified wafer hotspot to a corrected portion of the integrated circuit layout.

For purposes of this document, each process associated with the disclosed technology may be performed continuously and by one or more computing devices. Each step in a process may be performed by the same or different computing devices as those used in other steps, and each step need not necessarily be performed by a single computing device.

For purposes of this document, reference in the specification to “an embodiment,” “one embodiment,” “some embodiments,” or “another embodiment” may be used to described different embodiments and do not necessarily refer to the same embodiment.

For purposes of this document, a connection can be a direct connection or an indirect connection (e.g., via another part).

For purposes of this document, the term “set” of objects may refer to a “set” of one or more of the objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A system comprising:
a machine learning system configured to:
receive an input layout file that comprises a portion of an integrated circuit layout that includes a previously identified wafer hotspot;
match the previously identified wafer hotspot to one of a plurality of categories of wafer hotspot types; and
output a proposed layout modification associated with the matching category of wafer hotspot types.

2. The system of claim 1, wherein the image file comprises a label that designates the previously identified wafer hotspot.

3. The system of claim 1, wherein the image file comprises a Graphic Design System data file.

4. The system of claim 1, wherein each of the categories of wafer hotspot types comprises a corresponding category indicator.

5. The system of claim 1, wherein each of the categories of wafer hotspot types comprises a corresponding text description of the proposed layout modification.

6. The system of claim 1, wherein the machine learning system comprises a convolutional neural network.

7. The system of claim 1, wherein the machine learning system comprises an image-to-image translation predictor.

8. The system of claim 1, wherein the output comprises text.

9. The system of claim 1, wherein the output comprises an image.

10. The system of claim 1, wherein the machine learning system comprises a machine learning model trained to match previously identified wafer hotspots to one of N categories of wafer hotspots.

11. The system of claim 1, further comprising a graphical user interface configured to facilitate training and implementation of the machine learning system.

12. An apparatus comprising:
a first block configured to designate a previously identified wafer hotspot in an input layout file that comprises a portion of an integrated circuit layout;
a second block configured to convert information from the input layout file to generate an image of the portion of the integrated circuit layout with the previously identified wafer hotspot; and
a third block comprising a machine learning model configured to match the previously identified wafer hotspot to one of a plurality of categories of wafer hotspot types.

13. The apparatus of claim 12, wherein the input layout file comprises a Graphic Design System data file.

14. The apparatus of claim 12, wherein the image comprises TIFF, BMP, JPG, JPEG or PNG data.

15. The apparatus of claim 12, wherein each of the categories of wafer hotspot types comprises a corresponding text description of the proposed layout modification.

16. The apparatus of claim 12, wherein the third block is configured to output the text description of the proposed layout modification.

17. The apparatus of claim 12, wherein the machine learning model comprises a convolutional neural network.

18. An apparatus comprising:
a first block configured to designate a previously identified wafer hotspot in an input layout file that comprises a portion of an integrated circuit layout;
a second block configured to convert information from the input layout file to generate an image of the portion of the integrated circuit layout with the previously identified wafer hotspot; and
a third block comprising an image-to-image translation predictor configured to match the previously identified wafer hotspot to a corrected portion of the integrated circuit layout.

19. The apparatus of claim 18, wherein the third block is further configured to generate an output image file that depicts a same portion of the integrated circuit layout as the portion depicted in the input layout file, but with proposed changes to eliminate the previously identified wafer hotspot.

20. The apparatus of claim 18, wherein the input layout file comprises a Graphic Design System data file.
